(19) United States
(12) Patent Application Publication
(10) Pub. No.: US 2016/0362786 A1
(43) Pub. Date: Dec. 15, 2016

(54) Precursor Composition for Forming Zirconium-Containing Film and Method for Forming Zirconium-Containing Film Using Same

(71) Applicant: EUGENE TECHNOLOGY MATERIALS CO., LTD., Gyeonggi-do (KR)

(72) Inventors: Geun Su Lee, Gyeonggi-do (KR); Joung Min Han, Gyeonggi-do (KR)

(21) Appl. No.: 15/121,680

(22) PCT Filed: Feb. 26, 2015
(86) PCT No.: PCT/KR2015/001886

§ 371 Date: Aug. 25, 2016

(30) Foreign Application Priority Data
Feb. 26, 2014 (KR) 10-2014-0022892

(51) Int. Cl. C23C 16/455; C23C 16/34; H01L 21/02; C09D 1/00; H01L 21/285; C23C 16/06; C23C 16/50

(52) U.S. Cl. CPC C23C 16/45525; C23C 16/06; C23C 16/34; C23C 16/50; C09D 1/00; H01L 21/285; H01L 21/02189; H01L 21/0228; H01L 21/02205

(57) ABSTRACT

Disclosed are a precursor composition for forming a zirconium-containing film and a method for forming a zirconium-containing film by using the same, wherein the composition is characterized in that about 1 to 3 moles of a cycloaliphatic unsaturated compound represented by a particular chemical formula or an aromatic compound represented by a particular chemical formula: and about 1 to 3 moles of a cyclopentadienyl zirconium (IV)-based compound represented by a particular chemical formula are mixed. In the composition, the two constituent compounds are stable with each other and homogenously mixed with each other in a liquid state, without reacting with each other, and thus the composition behaves just like a single compound, and exhibits a high vapor pressure. The use of the composition of the present invention can obtain a zirconium-containing film, like high-quality zirconia, conveniently and economically.

### TECHNICAL FIELD

The present disclosure relates to a precursor composition for forming a zirconium-containing film and a method of forming a zirconium-containing film using the precursor composition, and more particularly, to a precursor composition for easily forming a zirconium-containing film such as a zirconia film in the manufacture of a semiconductor device, and a method of forming a zirconium-containing film using the precursor composition.

### BACKGROUND ART

Although an exemplary embodiment of forming a zirconia film with a zirconium precursor compound is described below, the zirconium precursor compound may also be applied to form a zirconium film or a zirconium nitride film.

Zirconia (ZrO₂) having a high dielectric constant of about 25, a wide band gap of about 5 eV, and a high refractive index of greater than about 2 may have good reactivity and also be chemically stable. Since zirconia is also thermally stable when it contacts a silicon (Si) interface, research has been conducted into various aspects for its application as a gate dielectric film or a capacitor dielectric film in the manufacture of a semiconductor device such as dynamic random access memory (DRAM).

In a conventional method of manufacturing semiconductor devices, normally, a zirconia film is formed using a metal organic chemical vapor deposition (MOCVD) or atomic layer deposition (ALD) process. MOCVD may form a high-quality zirconia film through CVD, and ALD may form a highly uniform zirconia film through atomic-scale uniformity control.

Therefore, to deposit a high-quality zirconia film through MOCVD or ALD, it is crucial to select a zirconium precursor compound suitable for the deposition process. When using MOCVD, it is necessary to convert a zirconium precursor compound into zirconia through rapid removal of a ligand present in the zirconium compound at 250 to 500° C. without thermally decomposing the ligand present in the zirconium precursor compound. When using ALD, it is necessary to rapidly and completely decompose and remove a ligand present in a zirconium precursor compound with an oxidizing agent such as ozone (O₃) or vapor (H₂O).

A zirconium precursor compound suitable for MOCVD or ALD is required to have may have a high vapor pressure at a low temperature (about 100° C.), be thermally stable against heat to vaporize, and be a liquid compound having low viscosity. A zirconium precursor compound that satisfies these requirements is suitable to form a zirconia thin film with homogeneous film quality and high density. In particular, a zirconium compound coordinated with amino group ligands is mostly used to deposit a zirconia film by ALD, because the zirconium compound is in a liquid state at room temperature with low viscosity and high vapor pressure, and the amino group ligands may be easily removable by ozone (O₃) and vapor (H₂O). However, such zirconium precursor compounds may have poor long-term storage characteristics, and in particular, poor thermal stability, and thus may be thermally decomposed during the deposition process, adversely affecting the quality of the zirconia film. Currently, tris(dimethylamino)cyclopentadienyl zirconium (IV) [CpZr(NMe₂)₃] is being most widely used as a zirconium precursor compound, but still has the above-described drawbacks.

### DETAILED DESCRIPTION OF THE INVENTION

### Technical Problem

To address the above-described drawbacks in the manufacture of a semiconductor device, the present invention provides a novel precursor composition for forming a high-quality zirconium-containing film, the novel precursor composition having a high vapor pressure at a low temperature, good long-term storage characteristics, and good thermal stability.

The present invention provides an easy method of forming a zirconium-containing film having good film characteristics, thickness uniformity, and good step coverage, by using the novel precursor composition for forming a high-quality zirconium-containing film.

### Technical Solution

According to an aspect of the present invention, there is provided a precursor composition for forming a zirconium-containing film, the precursor composition including a mixture of about 1 to 3 moles of either a cycloaliphatic unsaturated compound represented by Formula 1 or an aromatic compound represented by Formula 2, and about 1 to 3 moles of a cyclopentadienyl zirconium (IV)-based compound represented by Formula 3:

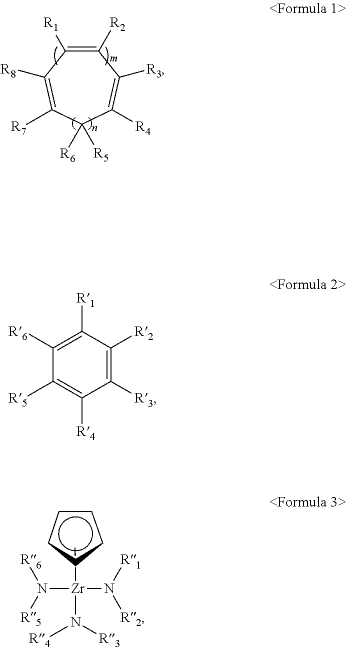

wherein, in Formula 1, R₁ to R₆ are the same as or differ from one another, and are each independently selected from a hydrogen atom, a C1 to C10 alkyl group, a C6 to C12 aryl group, and a C7 to C13 aralkyl group;

in Formula 2, R′₁ to R′₆ are the same as or differ from one another, and are each independently selected from a hydrogen atom, a C1 to C10 alkyl group, a C6 to C12 aryl group, and a C7 to C13 aralkyl group;

in Formula 3, R″₁ to R″₆ are the same as or differ from one another, and are each independently selected from a hydrogen atom, a C1 to C10 alkyl group, a C6 to C12 aryl group, and a C7 to C13 aralkyl group, wherein R″₁ and R″₂, R″₃, and R″₄, or R″₅ and R″₆ are linked to each other to form a C3 to C10 cyclic amine group together with a nitrogen atom linked thereto; and

m and n are each independently an integer selected from 0 to 10.

In some embodiments, the precursor composition may be a mixture of cycloheptatriene and tris(dimethylamino)cyclopentadienyl zirconium (IV) (CpZr(NMe₂)₃).

In some embodiments, the precursor composition may be a mixture of xylene and tris(dimethylamino)cyclopentadienyl zirconium (IV).

According to an aspect of the present invention, there is provided a method of forming a zirconium-containing film, the method including forming the zirconium-containing film on a substrate with a precursor compound according to any of the above-described embodiments as a precursor by a deposition process.

In some embodiments, the deposition process may be an atomic layer deposition (ALD) process or a chemical vapor deposition (CVD) process.

In some embodiments, the deposition process may be performed at about 50 to 700° C.

The zirconium-containing film may be a zirconium film, a zirconia film, or a zirconium nitride film.

In some embodiments, the method may include transferring the precursor composition for forming a zirconium-containing film onto the substrate as a mixture with at least one carrier gas or dilution gas selected from argon (Ar), nitrogen (N₂), is helium (He), and hydrogen (H₂).

In some embodiments, the method may include transferring the precursor composition for forming a zirconium-containing film onto the substrate as a mixture with at least one reaction gas selected from oxygen (O₂), vapor (H₂O), and ozone (O₃).

In some embodiments, the method may include transferring the precursor composition for forming a zirconium-containing film onto the substrate as a mixture with at least one reaction gas selected from ammonia (NH₃), hydrazine (N₂H₄), nitrogen dioxide (NO₂), and nitrogen (N₂) plasma.

In some embodiments, the method may include transferring the precursor composition for forming a zirconium-containing film onto the substrate by direct liquid injection (DLI), or by a liquid transfer method as a mixture with an organic solvent.

In some embodiments, heat energy, plasma, or an electrical bias may be applied to the substrate during the deposition process.

In some embodiments, the deposition process is used for forming a dielectric film of a capacitor or a gate electrode in manufacturing a semiconductor device.

In some embodiments, the deposition process may include:

heating the substrate to a temperature of about 50˜500° C. under a vacuum or inert atmosphere;

applying the precursor composition for forming a zirconium-containing film to the substrate after the precursor composition is heated to a temperature of about 20° C. to 100° C.;

adsorbing the precursor composition onto the substrate to form a layer including the precursor composition on the substrate; and

applying heat energy, plasma, or an electrical bias to the substrate to induce decomposition of the precursor composition in the layer including the precursor composition, thereby forming a zirconium-containing film on the substrate.

### Advantageous Effects

As described above, according to the one or more embodiments, a precursor composition for forming a zirconium-containing film may include either a cycloaliphatic unsaturated compound represented by Formula 1 or an aromatic compound represented by Formula 2, and a cyclopentadienyl zirconium (IV)-based compound represented by Formula 3, which may be mixed stably and homogeneously in liquid state without reacting with each other, and thus the precursor composition may be a volatile composition having a high vapor pressure at a temperature, for example, room temperature. The precursor composition may have good long-term storage stability and thermal stability, with less decomposition residue.

According to the one or more embodiments, a method of forming a zirconium-containing film with a precursor composition according to any of the above embodiments by chemical vapor deposition (CVD) or atomic layer deposition (ALD) which are generally used in the manufacture of a semiconductor device may provide the following advantages.

First, due to good thermal stability of the precursor composition, the temperature of a vaporizer and the deposition temperature may be increased during deposition, so that the resulting zirconium-containing film may have improved characteristics.

Second, due to good storage stability of the precursor composition with less decomposition residue, the temperature of a vaporizer and the deposition temperature may be increased, so that the resulting zirconium-containing film may have improved characteristics.

Third, due to high volatility with low viscosity, the precursor composition may have reduced intermolecular attraction, and thus may have good flowability and step coverage.

Therefore, a precursor composition for forming a zirconium-containing film, according to any of the above-described embodiments, may be used as a Zr precursor better than when the cyclopentadienyl zirconium (IV)-based compound represented by Formula 3 is used alone.

### DESCRIPTION OF THE DRAWINGS

### Best Mode

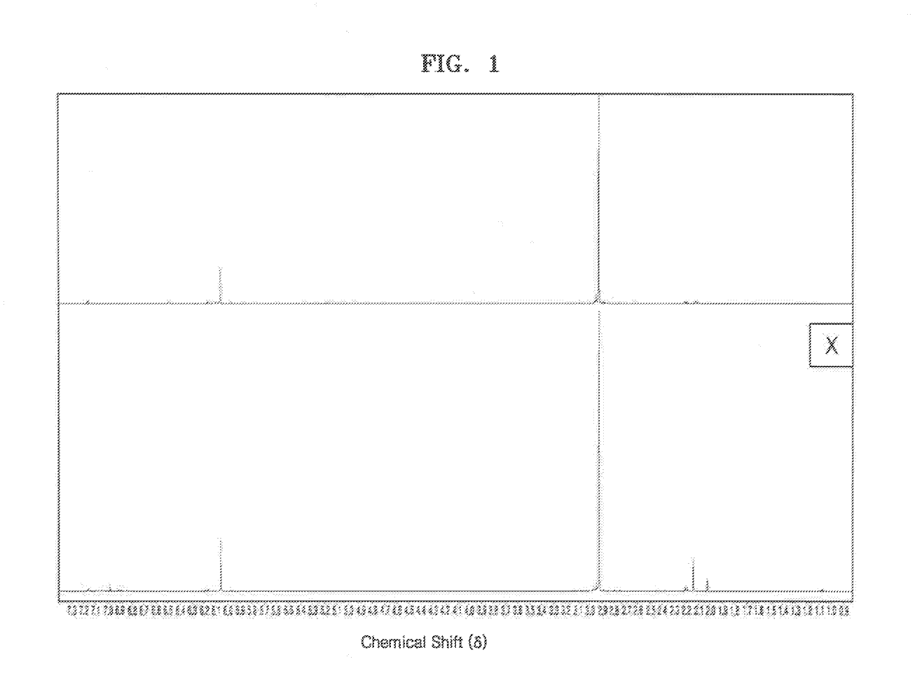

FIG. 1 illustrates nuclear magnetic resonance (NMR) spectra of precursor compositions X and Y of Examples 1 and 2 immediately after preparation:

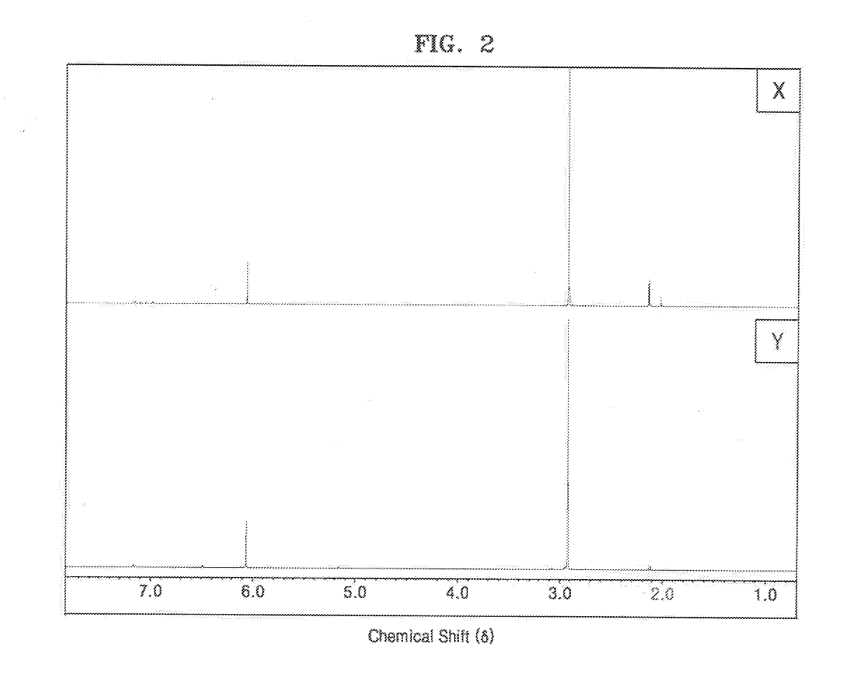

FIG. 2 illustrates NMR spectra of the precursor compositions X and Y of Examples 1 and 2 after a thermal stability test; and

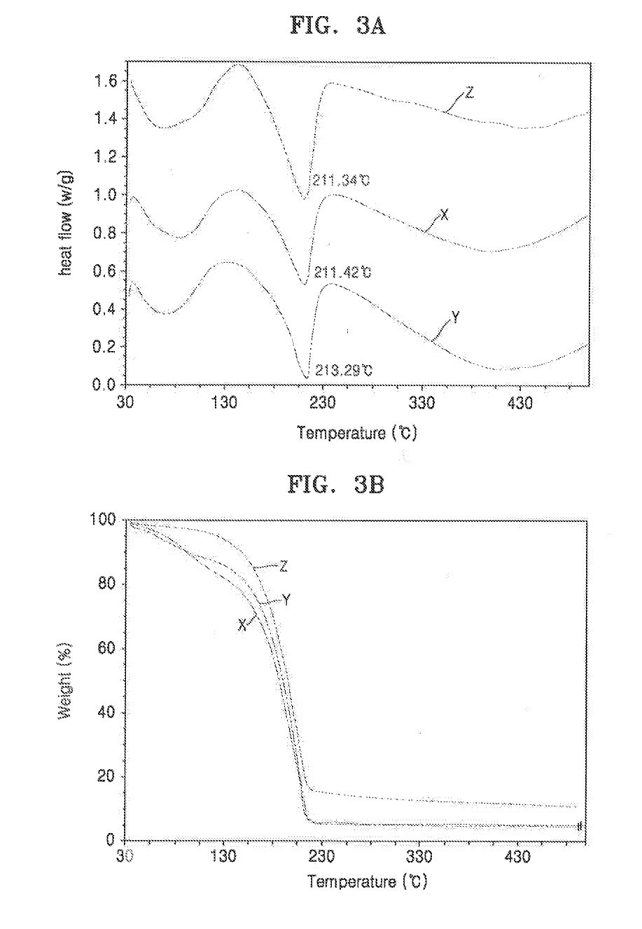

FIG. 3 illustrates a differential scanning calorimetric (DSC) thermal curve and a thermogravimetric analysis (TGA) thermal curve of the precursor compositions X and Y and tris(dimethylamino)cyclopentadienyl zirconium (IV) (TDCP) of Comparative Example wherein the upper thermal curve (a) in FIG. 3 illustrates a result of the DSC test and the lower thermal curve (b) illustrates a result of the TAG test.

### MODE OF THE INVENTION

Hereinafter, exemplary embodiments of a precursor composition for forming a zirconium-containing film and a method of forming a zirconium-containing film with any of the precursor compositions will be described in greater detail.

According to an aspect of the present disclosure, a precursor composition for forming a zirconium-containing film includes: a mixture of about 1 to 3 moles of either a cycloaliphatic unsaturated compound represented by Formula 1 or an aromatic compound represented by Formula 2, and about 1 to 3 moles of a cyclopentadienyl zirconium (IV)-based compound represented by Formula 3.

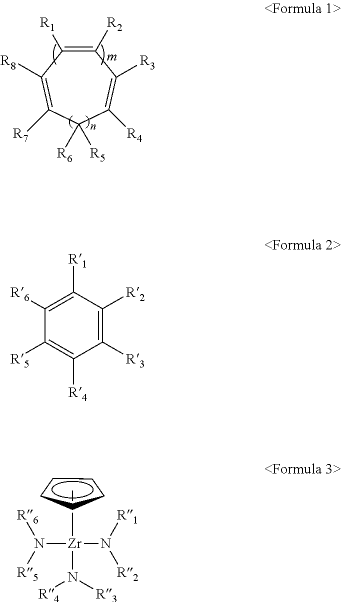

wherein, in Formula 1, R₁ to R₈, which may be the same as or differ from one another, may be each independently selected from a hydrogen atom, a C1 to C10 alkyl group, a C6 to C12 aryl group, and a C7 to C13 aralkyl group;

in Formula 2, R′₁ to R′₆, which may be the same as or differ from one another, may be each independently selected from a hydrogen atom, a C1 to C10 alkyl group, a C6 to C12 aryl group, and a C7 to C13 aralkyl group;

in Formula 3, R″₁ to R″₆, which may be the same as or differ from one another, may be each independently selected from a hydrogen atom, a C1 to 10 alkyl group, a C6 to 12 aryl group, and a C7 to C13 aralkyl group, wherein R″₁ and R″₂, R″₃ and R″₄, or R″₅ and R″₆ are linked to each other to form a C3 to C10 cyclic amine group together with a nitrogen atom linked thereto; and

m and n may be each independently an integer selected from 0 to 10.

In some embodiments, a mole ratio of the cycloaliphatic unsaturated compound represented by Formula 1 or the aromatic compound represented by Formula 2 to the cyclopentadienyl zirconium (IV)-based compound represented by Formula 3 may be about 1:2˜3, for example, about 1:2˜2.5, to prevent a chemical reaction between compound represented by Formula 1 or the compound represented by Formula 2 and the compound represented by Formula 3 and provide good thermal stability and storage stability to the precursor composition.

To prevent a chemical reaction between the compound represented by Formula 1 or the compound represented by Formula 2 and the compound represented by Formula 3 in the precursor composition and obtain the precursor composition with good storage stability without structural change of the compounds in the precursor composition, in Formulae 1 to 3, R₁ to R₈, R′₁ to R′₆, and R″₁ to R″₆, which may be the same as or differ from one another, may be each independently selected from a hydrogen atom and a C1 to C10 alkyl group; and m and n may be each independently an integer selected from 1 to 3.

Examples of the cycloaliphatic unsaturated compound represented by Formula 1 may include cycloheptatriene, cyclooctatriene, cyclononatetraene, and cyclooctadiene. For example, the cycloaliphatic unsaturated compound represented by Formula 1 may be cycloheptatriene, in view of preventing a chemical reaction with the cyclopentadienyl zirconium (IV)-based compound of Formula 3, good storage stability of the precursor composition without structural change of the compounds in the precursor composition, and an increase of the decomposition temperature of the precursor composition.

Examples of the aromatic compound represented by Formula 2 may include benzene, toluene, o-, m-, or p-xylene. For example, the aromatic compound of Formula 2 may be o-, m-, or p-xylene, in view of preventing a chemical reaction with the cyclopentadienyl zirconium (IV)-based compound of Formula 3, good storage stability of the precursor composition without chemical change in the precursor compounds, and an increase of the decomposition temperature of the precursor composition.

Examples of the cyclopentadienyl zirconium (IV)-based compound represented by Formula 3 may include tris(dimethylamino)cyclopentadienyl zirconium (IV) (CpZr(NMe₂)₃), tris(methylethylamino)cyclopentadienyl zirconium (IV) (CpZr(NMeEt)₃), tris(diethylamino)cyclopentadienyl zirconium (IV) (CpZr(NEt₂)₃), and tris(diisopropylamino)cyclopentadienyl zirconium (IV) (CpZr(N(i-Pr)₃).

In some embodiments, the precursor composition may be a mixture of cycloheptatriene and tris(dimethylamino)cyclopentadienyl zirconium (IV) (CpZr(NMe₂)₃). For example, the precursor composition may be a mixture of cycloheptatriene and tris(dimethylamino)cyclopentadienyl zirconium (IV) in a mole ratio of about 1:2.5.

In some other embodiments, the precursor composition may be a mixture of xylene and tris(dimethylamino)cyclopentadienyl zirconium (IV). For example, the SO precursor composition may be a mixture of xylene and tris(dimethylamino)cyclopentadienyl zirconium (IV) in a mole ratio of about 1:2.

The precursor composition for forming a zirconium-containing film, according to any of the above-described embodiments, may be a stable homogeneous composition including a mixture of the two compounds in a specific mole ratio, wherein precipitation of the two compounds through a reaction may be prevented, so that the precursor composition may form a zirconium-containing film by being spayed through a single nozzle.

As a stable homogeneous mixture present in liquid state without reacting between the compounds, the cycloaliphatic unsaturated compound represented by Formula 1 or the aromatic compound represented by Formula 2 and the cyclopentadienyl zirconium (IV)-based compound represented by Formula 3 may be mixed stably and homogeneously in liquid state without reacting with each other, and the precursor composition may be a volatile composition having a high vapor pressure at a temperature, for example, room temperature. The precursor composition according to any of the above-described embodiments may have good long-term storage stability and thermal stability, with less decomposition residue. Using a precursor composition for forming a zirconium-containing film, according to any of the above-described embodiments, a zirconium-containing film such as a zirconia film having good film characteristics, thickness uniformity, and good and step coverage may be easily and efficiently formed in a process of manufacturing a semiconductor device.

Hereinafter, exemplary embodiments of a method of forming a zirconium-containing film using a precursor composition for forming a zirconium-containing film, according to any of the above-described embodiments, will be described in greater detail.

A method of forming a zirconium-containing film, according to an embodiment, may include forming the zirconium-containing film on a substrate with a precursor compound according to any of the above-described embodiments as a precursor by a deposition process.

The deposition process may be an atomic layer deposition (ALD) process, or a chemical vapor deposition (CVD) process such as a metal organic chemical vapor deposition (MOCVD) process. The deposition process may be performed at room temperature to about 700° C., for example, at about 100 to 500° C. For example, the zirconium-containing film may be a zirconium film, a zirconia film, or a zirconium nitride film. A zirconium film formed using this method may be used as a conductive film. A zirconia film or a zirconium nitride film formed using this method may be used as a dielectric film or an insulating film. For example, the zirconia film may be used as a dielectric film of a capacitor or a gate electrode in the manufacture of a semiconductor device. For example, a process of forming a capacitor with the zirconia film may include: forming a lower electrode on a semiconductor substrate; forming a zirconia film using the method according to an embodiment; performing an oxidation treatment on the zirconia film using plasma in an oxygen-containing atmosphere; and forming an upper electrode on the zirconia film. The lower electrode may be a metal nitride film such as a titanium nitride film (TIN), a tantalum nitride film (TaN), and tungsten nitride film (WN); a preCious metal film such as a ruthenium (Ru) film and a platinum (Pt) film; or a combination of these films. The upper electrode may be a metal nitride film such as a titanium nitride film (TIN), a tantalum nitride film (TaN), and a tungsten nitride film (WN); a precious metal film such as a ruthenium (Ru) film and a platinum (Pt) film; or a combination of these films.

In some embodiments, when the zirconium-containing film is a zirconium film, during the deposition process, a precursor composition for forming the zirconium-containing film may be transferred onto a substrate as a mixture with at least one carrier gas or dilution gas selected from argon (Ar), nitrogen (N₂), helium (He), and hydrogen (H₂). In some embodiments, when the zirconium-containing film is a zirconia film, a precursor composition for forming the zirconium-containing film may be transferred onto a substrate as a mixture with at least one reaction gas selected from oxygen (O₂), vapor (H₂O), and ozone (O₃). In some other embodiments, when the zirconium-containing film is a zirconium nitride film, a precursor composition for forming the zirconium-containing film may be transferred onto a substrate as a mixture with at least one selected from ammonia (NH₃), hydrazine (N₂H₄), nitrogen dioxide (NO₂), and nitrogen (N₂) in plasma phase. For example, a precursor composition for forming a zirconium-containing film, according to any of the above-described embodiments, may be used for thin film deposition by being transferred onto a substrate with a bubbling method, a vapor phase mass flow controller (MFC) method, a direct liquid injection (DLI), or a liquid transfer method of transferring the precursor composition dissolved in an organic solvent.

To increase the deposition efficiency, heat energy, plasma, or an electrical bias may be applied to the substrate during the deposition process. For example, the deposition process may include: heating the substrate at a temperature of about 50 700° C. under a vacuum or inert atmosphere: applying the precursor composition for forming a zirconium-containing film to the substrate after the precursor composition is heated to a temperature of about 20° C. to 100° C.; adsorbing the, precursor composition onto the substrate to form a layer comprising the precursor composition on the substrate; applying heat energy, plasma, or an electrical bias to the substrate to induce decomposition of the precursor composition in the layer comprising the precursor composition, thereby forming the zirconium-containing film on the substrate.

In the deposition process, a time of about less than 1 minute may be allowed until the precursor composition layer is formed on the substrate. In some embodiments, an excess of the precursor composition that remains unadsorbed on the substrate may be removed using at least one inert gas such as argon (Ar), nitrogen (N₂), and helium (He). A time of about less than 1 minute may be allowed to remove the excess of the precursor composition remaining on the substrate. To remove an excess of reaction gas and byproducts, at least one inert gas such as argon (Ar), nitrogen (N₂), and helium (He) may be introduced into a chamber in less than 1 minute.

A precursor composition for forming a zirconium-containing film, according to any of the above-described embodiments, may have good chemical and thermal stability, and high volatility as a liquid at room temperature, and thus may be used as a precursor to deposit a zirconium-containing film by CVD or ALD in the manufacture of a semiconductor device.

One or more embodiments of a precursor composition for forming a zirconium-containing film and a method of forming a zirconium-containing film will now be described in detail with reference to the following examples. However, these examples are only for illustrative purposes and are not intended to limit the scope of the one or more embodiments of the present disclosure.

All process in the following examples were carried out using standard vacuum line Schlenk techniques, and all mixing processes were performed under an argon gas atmosphere. Before use in experiments, xylene and cycloheptatriene (available from Aldrich) were each stirred overnight together with CaH₂ to completely remove residual moisture, followed by fractional purification. Tris(dimethylamino)cyclopentadienyl zirconium (IV) (TDCP) was purchased from soulbrain ENG (Korea). All the materials were weighed in a glove box. Structural analysis of compounds and the prepared precursor composition was performed using a JEOL JNM-ECS 400 MHz NMR spectrophotometer (¹H-NMR 400 MHz). Benzene-d₆ as a solvent for nuclear magnetic resonance (NMR) analysis was stirred overnight together with CaH₂ to completely remove residual moisture before use. Thermal stability and decomposition temperature of each compound were analyzed using a TA-Q 600 instrument. The amount of each sample was about 10 mg.

### EXAMPLE 1

### Preparation of Precursor Composition

After 43.48 g (0.1507 mol) of TDCP was put into a 500-mL round-bottom flask with sidearm in a glove box at room temperature, the temperature was cooled down to 0° C., and 8 g (0.0753 mop of p-xylene was slowly added thereto, followed by slowly increasing the temperature of the mixture to room temperature, to thereby obtain a precursor composition X for forming a zirconium-containing film.

### EXAMPLE 2

### Preparation of Precursor Composition

After 39.14 g (0.1356 mol) of TDCP was put into a 500-mL round-bottom flask with sidearm in a glove box at room temperature, the temperature was cooled down to 0° C., and 5 g (0.05426 mol) of cycloheptatriene was slowly added thereto, followed by slowly increasing the temperature of the mixture to room temperature, to thereby obtain a precursor composition Y for forming a zirconium-containing film.

### COMPARATIVE EXAMPLE 1

### Use of TDCP Alone

TDCP purchased from soulbrain ENG (Korea) was used alone.

<NMR Spectrometry >

The precursor compositions X and Y of Examples 1 and 2 immediately after the preparation were analyzed by nuclear magnetic resonance (NMR) spectroscopy. FIG. 1 illustrates NMR spectra of the precursor compositions X and Y of Examples 1 and 2 immediately after the preparation.

Referring to FIG. 1, the precursor compositions X and Y of Examples 1 and 2 both exhibited a peak at a chemical shift δ=6.06 ppm due to the cyclopentadienyl (Cp) group of the TDCP, a peak at a chemical shift δ=2.93 ppm due to the diethylamine (DMA) group of the TDCP, and a peak at a chemical shift δ=2.92 ppm due to xylene or cycloheptatriene used as the organic solvent.

Therefore, it was found that no chemical reaction occurred between TDCP and p-xylene in the precursor composition X of Example 1, or between TDCP and cycloheptatriene in the precursor composition Y of Example 2, and characteristics of the precursor compositions X and Y remained as they were.

After a thermal stability test, in which the precursor compositions X and Y were heated to about 200° C. and maintained at this temperature for about 16 hours, the precursor compositions X and Y were analyzed by NMR spectroscopy.

FIG. 2 illustrates NMR spectra of the precursor compositions X and Y as the results of the NMR spectroscopy after the thermal stability test.

Referring to FIG. 2, no difference from the NMR of FIG. 1 is found, indicating that no thermal decomposition of the components occurred in the precursor compositions X and Y even after heating at about 200° C. for about 16 hours. These experimental results indicate that the precursor compositions X and Y are thermally and chemically very stable. Due to the good thermal stability of the precursor compositions X and Y, a zirconium-containing film deposited using the precursor composition X or Y may have improved film characteristics.

<Thermal Analysis>

Differential scanning calorimetric (DSC) analysis and thermogravimetric analysis (TGA) tests were performed on the precursor compositions X and Y of Examples 1 and 2 and the TDCP of Comparative Example 1, using a thermal analyzer (SDT Q600, available from TA Instruments) in a DSC mode for thermal decomposition temperature measurements and a TGA mode for measuring the amount of residue, respectively.

The thermal analysis conditions for thermal decomposition temperature measurements were as follows:

Carrier gas: argon (Ar) gas,

Carrier gas flow rate: 100 cc/min,

Heating profile: heated at a temperature from 30° C. to 500° C. at a temperature rise rate of about 10° C/min.

In the DSC test, the thermal decomposition temperature was determined as the temperature at which the amount of heat flow began to rise dramatically following the dropping with a temperature rise in a DSC thermal curve (thermogram) of FIG. 3.

FIG. 3 illustrates a DSC thermal curve and a TGA thermal curve of the precursor compositions X and Y and the TDCP of Comparative Example 1, wherein the upper thermal curve (a) in FIG. 3 illustrates a result of the DSC test and the lower thermal curve (b) illustrates a result of the TAG test.

Referring to FIG. 3, the precursor compositions X and Y each exhibited a single decomposition temperature, which is a single compound-like behavior, as if they included a single compound. This is very favorable characteristics in forming a zirconium-containing film with the precursor compositions X and Y. The thermal decomposition temperatures and the amounts of residue of the precursor compositions X and Y of Examples 1 and 2 and the TDCP of Comparative Example 1 were obtained based on the thermograms of FIG. 3. The results are shown in Table 1.

TABLE 1

| | | Precursor | Precursor |
|---|---|---|---|
| | TDCP | composition X | composition Y |
| Decomposition | 211.34 | 211.42 | 213.29 |
| temperature (° C.) | | | |
| Amount of residue (%) | 11.88 | 4.68 | 5.06 |

Referring to Table 1, through the DSC test, the TDCP of Comparative Example 1 and the precursor compositions X and composition Y of Examples 1 and 2 were found to have a decomposition temperature of about 211.34° C., about 211.42° C., and about 213.29° C., respectively. In particular, the precursor compound Y of Example 2 having a higher decomposition temperature than that of the TDCP of Comparative Example 1, is found to be suitable for deposition at high temperature.

The amounts of residue in the TDCP of Comparative Example 1 and the precursor compositions X and Y of Examples 1 and 2 after the heating to about 500° C. were found to be about 11.88%, 4.66%, and 5.06%, respectively. The amount of residue was represented in percentage based on a total weight of the sample before the heating. It is found from the results that forming a zirconium-containing film by deposition with the precursor compositions X and Y of Examples 1 and 2 may be convenient due to less contamination of a semiconductor substrate, compared to when using the TDCP alone of Comparative Example 1.

<Viscosity Measurement>

Viscosities of the TDCP of Comparative Example 1 and the precursor compositions X and Y of Examples 1 and 2 were measured.

In particular, a viscometer (SV-10, available from AND, Japan) was placed in a glove box, and the viscosity of each of the TDCP of Comparative Example 1, and the precursor compositions X and Y of Examples 1 and 2 immediately after the preparation was measured five times in total with the viscometer at a temperature of about 11° C. in the glove box. After a thermal stability test on the TDCP of Comparative Example 1 and the precursor compositions X and Y of Examples 1 and 2 at about 200° C. for about 2 hours, the viscosity measurement was performed five times in total in the glove box having an inner temperature of about 11° C. The test results are shown in Table 2.

TABLE 2

| | Viscosity (centipoise) | |
|---|---|---|
| | Before heating | |
| | at 200° C. | After heating at 200° C. |
| TDCP | 18.5 | 16.5 |
| Precursor composition X | 6.1 | 4.7 |
| Precursor composition Y | 7.8 | 9.7 |

Referring Table 2, the precursor compositions X and Y of Examples 1 and 2 were found to have a lower viscosity than the TDCP of Comparative Example 1 both before and after the heating. Accordingly, it is found that the precursor compositions X and Y of Examples 1 and 2 may both have good volatility with weak intermolecular attraction, compared to the TDCP of Comparative Example 1, and thus a zirconium-containing film formed using any of the precursor compositions X and Y of Examples 1 and 2 may have improved step coverage.

### EXAMPLE 3

### Zirconia Film Deposition Test

Zirconia film formability of each of the precursor compositions X and Y of Examples 1 and 2 by plasma enhanced atomic layer deposition (PEALD) was evaluated. Argon as inert gas was used as a purge and precursor-carrier gas. A zirconia film was deposited on a P-type (100) Si wafer through ALD cycles of the precursor compositions, argon, plasma, and argon injections.

### EXPLANATION OF REFERENCE CHARACTERS

X: composition X

Y: composition Y

Z: TDCP

1. A precursor composition for forming a zirconium-containing film, comprising a mixture of about 1 to 3 moles of either a cycloaliphatic unsaturated compound represented by Formula 1 or an aromatic compound represented by Formula 2, and about 1 to 3 moles of a cyclopentadienyl zirconium (IV)-based compound represented by Formula 3: 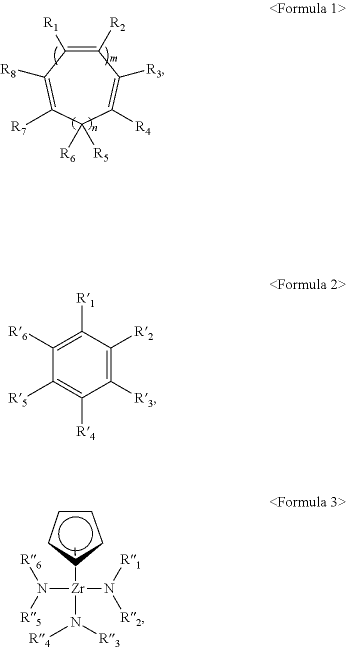
wherein, in Formula 1, R₁ to R₈ are the same as or differ from one another, and are each independently selected from a hydrogen atom, a C1 to C10 alkyl group, a C6 to C12 aryl group, and a C7 to C13 aralkyl group;
in, in Formula 2, R′₁ to R′₆ are the same as or differ from one another, and are each independently selected from a hydrogen atom, a C1 to C10 alkyl group, a C6 to C12 aryl group, and a C7 to C13 aralkyl group;
in Formula 3, R″₁ to R″₆ are the same as or differ from one another, and are each independently selected from a hydrogen atom, a C1 to 10 alkyl group, a C6 to 12 aryl group, and a C7 to C13 aralkyl group, wherein R″₁ and R″₂, R″₃ and R″₄, or R″₅ and R″₆ are linked to each other to form a C3 to C10 cyclic amine group together with a nitrogen atom linked thereto; and
m and n are each independently an integer selected from 0 to 10.

2. The precursor composition of claim 1, wherein the precursor composition is a mixture of cycloheptatriene and tris(dimethylamino)cyclopentadienyl zirconium (IV) (CpZr(NMe₂)₃).

3. The precursor composition of claim 1, wherein the precursor composition is a mixture of xylene and tris(dimethylamino)cyclopentadienyl zirconium (IV).

4. A method of forming a zirconium containing film, the method comprising forming the zirconium-containing film on a substrate with the precursor compound according to claim 1 as a precursor by a deposition process.

5. The method of claim 4, wherein the deposition process is an atomic layer deposition (ALD) process or a chemical vapor deposition (CVD) process.

6. The method of claim 4, wherein the deposition process is performed at about 50 to 700° C.

7. The method of claim 4, wherein the zirconium-containing film is a zirconium film, a zirconia film, or a zirconium nitride film.

8. The method of claim 4, wherein the method comprises transferring the precursor composition for forming a zirconium-containing film onto the substrate as a mixture with at least one carrier gas or dilution gas selected from argon (Ar), nitrogen (N₂), helium (He), and hydrogen (H₂).

9. The method of claim 4, wherein the method comprises transferring the precursor composition for forming a zirconium-containing film onto the substrate as a mixture with at least one reaction gas selected from oxygen (O₂), vapor (H₂O), and ozone (O₃).

10. The method of claim 4, wherein the method comprises transferring the precursor composition for forming a zirconium-containing film onto the substrate as a mixture with at least one reaction gas selected from ammonia (NH₃), hydrazine (N₂H₄), nitrogen dioxide (NO₂), and nitrogen (N₂) plasma.

11. The method of claim 4, wherein the method comprises transferring the precursor composition for forming a zirconium-containing film onto the substrate by direct liquid injection (DLI), or by a liquid transfer method as a mixture with an organic solvent.

12. The method of claim 4, wherein heat energy, plasma, or an electrical bias is applied to the substrate during the deposition process.

13. The method of claim 4, wherein the deposition process is used for forming a dielectric film of a capacitor or a gate electrode in manufacturing a semiconductor device.

14. A method of forming a zirconium-containing film, the method comprising forming the zirconium-containing film on a substrate with the precursor compound according to claim 2 as a precursor by a deposition process.

15. A method of forming a zirconium-containing film, the method comprising forming the zirconium-containing film on a substrate with the precursor compound according to claim 3 as a precursor by a deposition process.
